(19) United States
(12) Patent Application Publication
(10) Pub. No.: US 2026/0026220 A1
(43) Pub. Date: Jan. 22, 2026

(54) DISPLAY DEVICE AND ELECTRONIC DEVICE INCLUDING THE SAME

(71) Applicant: Samsung Display Co., Ltd., Yongin-Si (KR)

(72) Inventors: SUJEONG KIM, Yongin-si (KR); DAEGEUN LEE, Yongin-si (KR); EUNJEONG JEON, Yongin-si (KR); SEOUNGBUM PYOUN, Yongin-si (KR)

(21) Appl. No.: 19/181,337

(22) Filed: Apr. 17, 2025

(30) Foreign Application Priority Data
Jul. 16, 2024 (KR) 10-2024-0093821

(51) Int. Cl. H10K 59/131; H10K 59/95

(52) U.S. Cl. CPC H10K 59/131; H10K 59/95

(57) ABSTRACT

A display device is disclosed that includes a display panel, which includes pad electrodes, and a driver disposed on the display panel and including bump electrodes. A bump electrode includes protrusion members, which protrude to be adjacent to the display panel, and a bonding layer covering the protrusion members and comprising a metal. A portion of the bonding layer is in contact with a pad electrode. The protrusion members include first row protrusion members arranged in a first direction, and second row protrusion members spaced apart from the first row protrusion members in a second direction crossing the first direction and arranged in the first direction. At least some of the first row protrusion members and the second row protrusion members are disposed alternately to not align with each other in the second direction.

### CROSS-REFERENCE TO RELATED APPLICATIONS

This U.S. non-provisional patent application claims priority under 35 U.S.C. § 119 of Korean Patent Application No. 10-2024-0093821, filed on Jul. 16, 2024, the entire contents of which are hereby incorporated by reference.

### BACKGROUND

The present disclosure relates to a display device and an electronic device including the display device, and more particularly, to a display device including a driver and a bump electrode included therein.

Electronic equipment for providing images to users such as smartphones, digital cameras, laptop computers, navigation devices, and smart televisions include a display device for displaying an image. A display device generates images in a display screen, which are viewed by a user.

Such a display device includes a display panel on which an image is displayed. The display panel includes a plurality of gate lines, a plurality of data lines, and a plurality of pixels connected to the plurality of gate lines and the plurality of data lines.

The display panel may be connected to a driver that provides an electrical signal required for displaying an image to the gate lines or the data lines.

### SUMMARY

The present disclosure provides a display device and an electronic device having improved electrical connection characteristics between a pad electrode and a bump electrode.

An embodiment of a display device includes: a display panel including a display area, on which a pixel is disposed, and a non-display area, on which a plurality of pad electrodes are disposed; and a driver disposed on the display panel and including a plurality of pump electrodes, each of which is disposed to correspond to each of the plurality pad electrodes. In an embodiment, each of the plurality of bump electrodes may include: a plurality of protrusion members protruding to be adjacent to the display panel; and a bonding layer which is configured to cover each of the plurality of protrusion members and which includes a metal, a portion of the bonding layer is in contact with one of the plurality of pad electrodes. In an embodiment, the plurality of protrusion members may include: a plurality of first row protrusion members arranged in a first direction; and a plurality of second row protrusion members spaced apart from the plurality of first row protrusion members in a second direction crossing the first direction and arranged along the first direction. In an embodiment, at least some of the plurality of first row protrusion members and the plurality of second row protrusion members may be disposed alternately to not align with each other in the second direction.

In an embodiment, the display device may further include a first adhesive layer disposed between the display panel and the driver to bond the display panel to the driver. In an embodiment, the first adhesive layer may include a non-conductive film.

In an embodiment, the driver may further include a driver-integrated circuit that includes a base surface adjacent to the display panel. In an embodiment, the plurality of bump electrodes may be disposed between the base surface and the display panel.

In an embodiment, each of the plurality of bump electrodes may include an intermediate layer disposed between each of the plurality of protrusion members and the bonding layer.

In an embodiment, the plurality of protrusion members may further include: a plurality of third row protrusion members spaced apart from the plurality of first row protrusion members and the plurality of second row protrusion members in the second direction and arranged along the first direction; and a plurality of fourth row protrusion members spaced apart from the plurality of first row protrusion members, the plurality of second row protrusion members, and the plurality of third row protrusion members in the second direction and arranged along the first direction.

In an embodiment, at least some of the plurality of second row protrusion members and the plurality of third row protrusion members may be arranged parallel to the second direction. In an embodiment, at least some of the plurality of first row protrusion members and the plurality of fourth row protrusion members may be arranged parallel to the second direction.

In an embodiment, at least some of the plurality of first row protrusion members and the plurality of third row protrusion members may be arranged parallel to the second direction. In an embodiment, at least some of the plurality of second row protrusion members and the plurality of fourth row protrusion members may be arranged parallel to the second direction.

In an embodiment, the sum of the number of plurality of first row protrusion members and the number of plurality of second row protrusion members may be greater than that of the number of plurality of third row protrusion members and the number of fourth row protrusion members.

In an embodiment, each of the plurality of bump electrodes may include: a first connection area on which the plurality of first row protrusion members and the plurality of second row protrusion members are disposed; a second connection area on which the plurality of third row protrusion members and the plurality of fourth row protrusion members are disposed; and an inspection area on which the plurality of protrusion members are not disposed, In an embodiment, the inspection area may be disposed between the first connection area and the second connection area on a plane.

In an embodiment, each of the plurality of bump electrodes may include: a first connection area on which the plurality of first row protrusion members and the plurality of second row protrusion members are disposed; a second connection area on which the plurality of third row protrusion members and the plurality of fourth row protrusion members are disposed; and an inspection area on which the plurality of protrusion members are not disposed. In an embodiment, the inspection area may be disposed at one side of one of the first connection area and the second connection area on a plane and is spaced apart from the other.

In an embodiment, the number of plurality of first row protrusion members may be less than the number of plurality of second row protrusion members.

In an embodiment, when a surface area of each of the plurality of bump electrodes is defined as A, and a product of a surface area and the number of each of the plurality of protruding members included in the plurality of bump electrodes is defined as B, following Equation 1 is satisfied:

0.0012≤B/A≤0.0146 [Equation 1]

In an embodiment, each of the plurality of protrusion members may include a polymer material.

In an embodiment, each of the plurality of protrusion members may have a width that gradually decreases as towards the display panel.

In an embodiment, the plurality of bump electrodes may include: a plurality of first bump electrodes arranged along the first direction; and a plurality of second bump electrodes spaced apart from the plurality of first bump electrodes in the second direction and arranged along the first direction. In an embodiment, the driver may include: a first long side extending in the first direction; a second long side extending in the first direction and spaced apart from the first long side along the second direction; a first short side extending in the second direction to connect the first long side to the second long side; and a second short side extending in the second direction and spaced apart from the first short side along the first direction. In an embodiment, the plurality of first bump electrodes may be disposed adjacent to the first long side, and the plurality of second bump electrodes may be disposed adjacent to the second long side.

In an embodiment, each of the plurality of first row protrusion members may be spaced apart from each of the plurality of second row protrusion members in a diagonal direction that is a direction between the first direction and the second direction.

An embodiment of a display device includes: a display panel including a display area on which a pixel is disposed and a non-display area on which a plurality of pad electrodes are disposed; and a driver disposed on the display panel and including a plurality of bump electrodes, which are disposed to correspond to the plurality of pad electrodes, respectively. In an embodiment, the plurality of bump electrodes may include: a plurality of protrusion members protruding to be adjacent to the display panel; and a bonding layer which is configured to cover each of the plurality of protrusion members, a portion of the bonding layer is in contact with one of the plurality of pad electrodes. In an embodiment, the plurality of protrusion members may include: a plurality of first row protrusion members arranged in a first direction; and a plurality of second row protrusion members spaced apart from the plurality of first row protrusion members in a second direction crossing the first direction and arranged along the first direction. In an embodiment, each of the plurality of first row protrusion members may be spaced apart from each of the plurality of second row protrusion members in a diagonal direction that is a direction between the first direction and the second direction.

In an embodiment, the plurality of protrusion members may further include: a plurality of third row protrusion members spaced apart from the plurality of first row protrusion members and the plurality of second row protrusion members in the second direction and arranged along the first direction; and a plurality of fourth row protrusion members spaced apart from the plurality of first row protrusion members, the plurality of second row protrusion members, and the plurality of third row protrusion members in the second direction and arranged along the first direction. In an embodiment, each of the plurality of third row protrusion members may be spaced apart from each of the plurality of fourth row protrusion members in the diagonal direction.

In an embodiment, at least some of each of the plurality of second row protrusion members and each of the plurality of third row protrusion members may be arranged parallel to the second direction. In an embodiment, at least some of each of the plurality of first row protrusion members and each of the plurality of fourth row protrusion members may be arranged parallel to the second direction.

An embodiment of an electronic device includes: a display panel including a display area on which a pixel is disposed and a non-display area on which a plurality of pad electrodes are disposed; electronic modules electrically connected to the display panel; a driver disposed on the display panel and including a plurality of bump electrodes, which are disposed to correspond to the plurality of pad electrodes, respectively; and a first adhesive layer disposed between the display panel and the driver to bond the display panel to the driver. In an embodiment, the first adhesive layer may include a non-conductive film. In an embodiment, each of the plurality of the plurality of bump electrodes may include: a plurality of protrusion members protruding to be adjacent to the display panel; and a bonding layer which is configured to cover each of the plurality of protrusion members, a portion of the bonding layer is in contact with one of the plurality of pad electrodes. In an embodiment, the plurality of protrusion members may include: a plurality of first row protrusion members arranged in a first direction; and a plurality of second row protrusion members spaced apart from the plurality of first row protrusion members in a second direction crossing the first direction and arranged along the first direction. In an embodiment, at least some of the plurality of first row protrusion members and the plurality of second row protrusion members may be disposed alternately to not align with each other in the second direction.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an electronic apparatus according to an embodiment of the inventive concept;

FIG. 2 is an exploded perspective view of the electronic apparatus according to an embodiment of the inventive concept;

FIG. 3 is a cross-sectional view of a display device according to an embodiment of the inventive concept;

FIG. 4 is a plan view of a display panel according to an embodiment of the inventive concept;

FIG. 5 is a cross-sectional view of a pixel according to an embodiment of the inventive concept;

FIG. 6 is a side view of the display device according to an embodiment of the inventive concept;

FIG. 7 is an enlarged perspective view illustrating a portion of the display device according to an embodiment of the inventive concept;

FIG. 8 is a plan view of a driver according to an embodiment of the inventive concept;

FIG. 9 is a plan view illustrating one of first bump electrodes included in the driver according to an embodiment of the inventive concept;

FIGS. 10A and 10B are cross-sectional views illustrating a portion of the display device according to an embodiment of the inventive concept;

FIGS. 11A, 11B, and 11C are plan views illustrating one of the first bump electrodes included in the driver according to an embodiment of the inventive concept; and

FIG. 12 is a plan view illustrating a portion of constituents of the display device according to an embodiment of the inventive concept.

### DETAILED DESCRIPTION

In this specification, it will also be understood that when one component (or region, layer, portion, etc.) is referred to as being ‘on’, ‘connected to’, or ‘coupled to’ another component, it can be directly connected/coupled on/to the one component, or an intervening third component may also be present.

Like reference numerals refer to like elements throughout. Also, in the figures, the thickness, ratio, and dimensions of components are exaggerated for clarity of illustration.

It will be understood that although the terms such as ‘first’ and ‘second’ are used herein to describe various elements, these elements should not be limited by these terms. The terms are only used to distinguish one component from other components. For example, a first element referred to as a first element in an embodiment can be referred to as a second element in another embodiment without departing from the scope of the appended claims. The terms of a singular form may include plural forms unless referred to the contrary.

Also, “under”, “below”, “above’, “upper”, and the like are used for explaining relation association of components illustrated in the drawings. The terms may be a relative concept and described based on directions expressed in the drawings.

The meaning of each of “include” and “comprise” specifies a property, a fixed number, a step, an operation, an element, a component or a combination thereof, but does not exclude other properties, fixed numbers, steps, operations, elements, components or combinations thereof.

In this specification, “directly disposed” may mean that there is no layer, film, region, plate, or the like between a portion of the layer, the layer, the region, the plate, or the like and the other portion. For example, “directly disposed” may mean being disposed without using an additional member such and an adhesion member between two layers or two members.

Unless otherwise defined, all terms (including technical and scientific terms) used herein have the same meaning as commonly understood by a person of ordinary skill in the art to which this invention belongs. In addition, terms such as those defined in commonly used dictionaries should be interpreted as having meanings consistent with their meanings in the context of the relevant technology, and unless explicitly defined, it should not be interpreted in an overly idealistic or overly formal sense.

Hereinafter, embodiments of the inventive concept will be described with reference to the accompanying drawings.

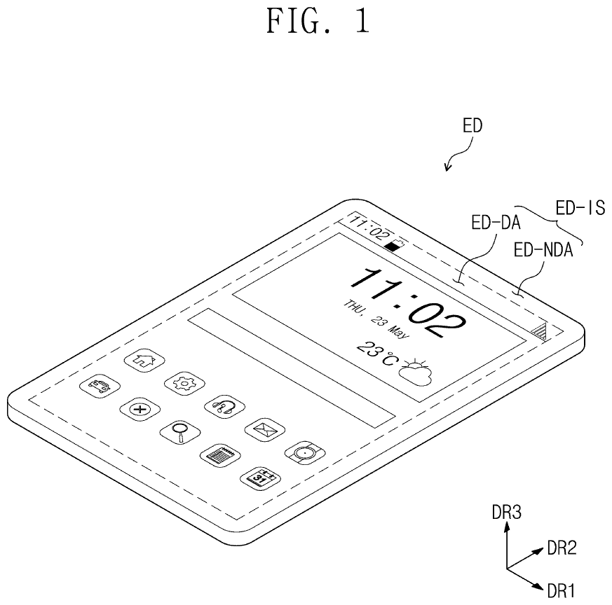

FIG. 1 is a perspective view of an electronic apparatus according to an embodiment of the inventive concept.

Referring to FIG. 1, an electronic apparatus ED may have a rectangular shape having short sides extending in a first direction DR1 and long sides extending in a second direction DR2 crossing the first direction DR1. However, this embodiment is not limited thereto, and the electronic apparatus ED may have various shapes such as circular and polygonal shapes.

Hereinafter, a direction substantially perpendicularly crossing a plane defined by the first direction DR1 and the second direction DR2 may be defined as a third direction DR3. In addition, in this specification “when viewed on the plane” may be defined in a state when viewed in the third direction DR3.

A top surface of the electronic apparatus ED may be defined as a display surface ED-IS, and the display surface ED-IS may have a plane defined by the first direction DR1 and the second direction DR2. Images IM generated in the electronic apparatus ED may be provided to a user through the display surface ED-IS.

The display area ED-IS may include a display area ED-DA and a non-display area ED-NDA surrounding the display area ED-DA. The display area ED-DA may display an image, and the non-display area ED-NDA may not display an image. The non-display area ED-NDA may surround the display area ED-DA and define an edge of the electronic apparatus ED that is printed in a predetermined color.

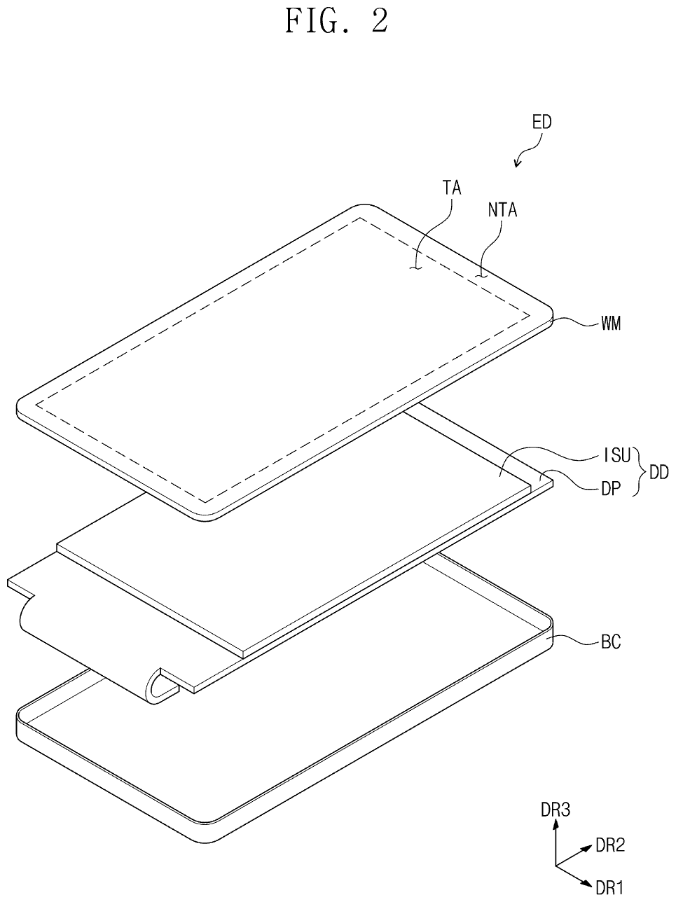

FIG. 2 is an exploded perspective view of the electronic apparatus according to an embodiment of the inventive concept.

Referring to FIG. 2, the electronic apparatus ED may include a window WM, a display device DD, and a housing BC. The housing BC may accommodate the display device DD and be coupled to the window WM. Although not shown, the electronic apparatus ED may further include other electronic modules accommodated in the housing BC and electrically connected to the display panel DP. For example, the electronic apparatus ED may further include a main board, a circuit module mounted on the main board, a camera module, a power module, etc.

The window WM may be disposed above the display device DD. The window WM may transmit images provided from the display device DD to the outside. The window WM may include a transmission area TA and a non-transmission area NTA. The transmission area TA may overlap the display area ED-DA of FIG. 1. The transmission area TA may have a shape corresponding to the display area ED-DA.

The non-transparent area NTA may overlap the non-display area ED-NDA (see FIG. 1) and may have a shape corresponding to the non-display area ED-NDA (see FIG. 1). The non-transmission area NTA may be an area having a light transmittance that is relatively less than that of the transmission area TA.

The display device DD may generate images and detect an external input. The display device DD may include a display panel DP and an input sensor ISU. Although not shown, the display device DD may further include an anti-reflection member disposed on the input sensor ISU. The anti-reflection material may include a polarizer and a retarder or may include a color filter and a black matrix.

The display panel DP may be an emission-type display panel, and the embodiment of the inventive concept is not limited to kinds of display panels. For example, the display panel DP may be an organic light emitting display panel or an inorganic light emitting display panel. An emission layer of the organic light emitting display panel may include an organic light emitting material. The emission layer of the inorganic light emitting display panel may include quantum dots, quantum rods, nano LEDs, etc. Hereinafter, the organic light emitting display panel will be described as an example of the display panel DP.

The input sensor ISU may include any one of a capacitive sensor, an optical sensor, an ultrasonic sensor, and an electromagnetic induction sensor. The input sensor ISU may be provided on the display panel DP through a continuous process or may be manufactured separately and then attached to an upper side of the display panel DP through an adhesive layer.

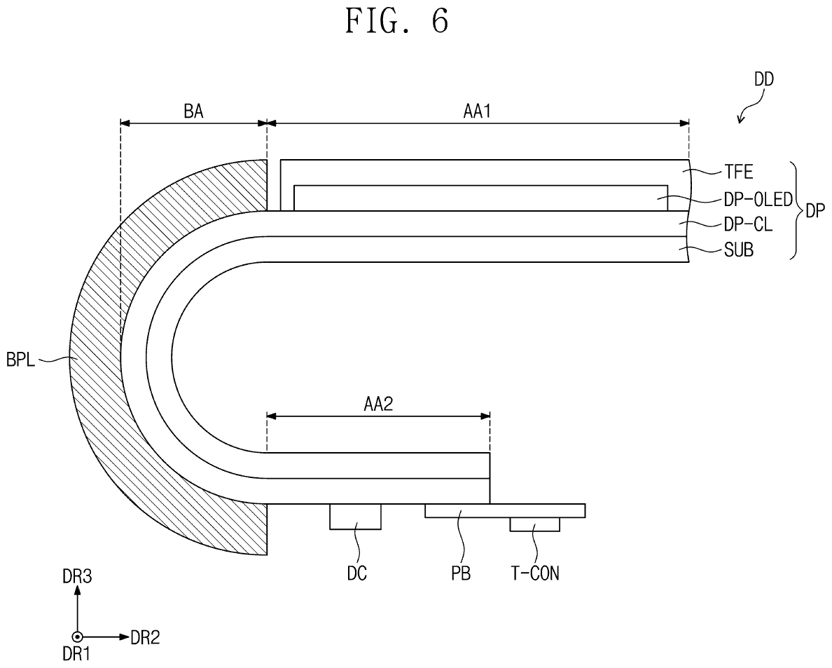

In the display device DD according to an embodiment, a portion of the display panel DP may be bent so that a driver DC (see FIG. 6) faces downward. The non-display area ED-NDA (see FIG. 1) of the display panel DP may be bent. However, the bent portion is not limited thereto, and the circuit board PB (see FIG. 6) may be bent without bending the display panel DP.

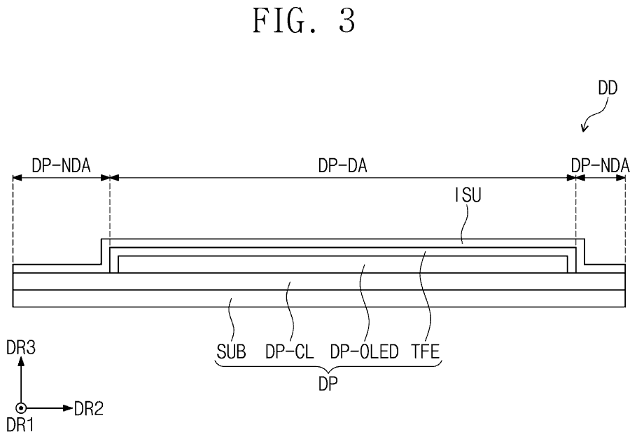

FIG. 3 is a cross-sectional view of the display device according to an embodiment of the inventive concept.

Referring to FIG. 3, the display panel DP may include a substrate SUB, a circuit element layer DP-CL disposed on the substrate SUB, a display element layer DP-OLED, and a thin film encapsulation layer TFE. The input sensor ISU may be disposed on the thin film encapsulation layer TFE.

The substrate SUB may include a display area DP-DA and a non-display area DP-NDA around the display area DP-DA. The substrate SUB may include glass or a flexible plastic material such as polyimide (PI). The display element layer DP-OLED may be disposed on the display area DP-DA.

A plurality of pixels may be disposed on the circuit element layer DP-CL and the display element layer DP-OLED. Although not shown, each of the pixels may include a plurality of transistors and at least one capacitor, which are disposed on the circuit element layer DP-CL, and a light emitting element disposed on the display element layer DP-OLED and connected to the transistors.

The thin film encapsulation layer TFE may be disposed on the circuit element layer DP-CL to cover the display element layer DP-OLED. The thin film encapsulation layer TFE may protect the pixels from moisture, oxygen, and external foreign substances.

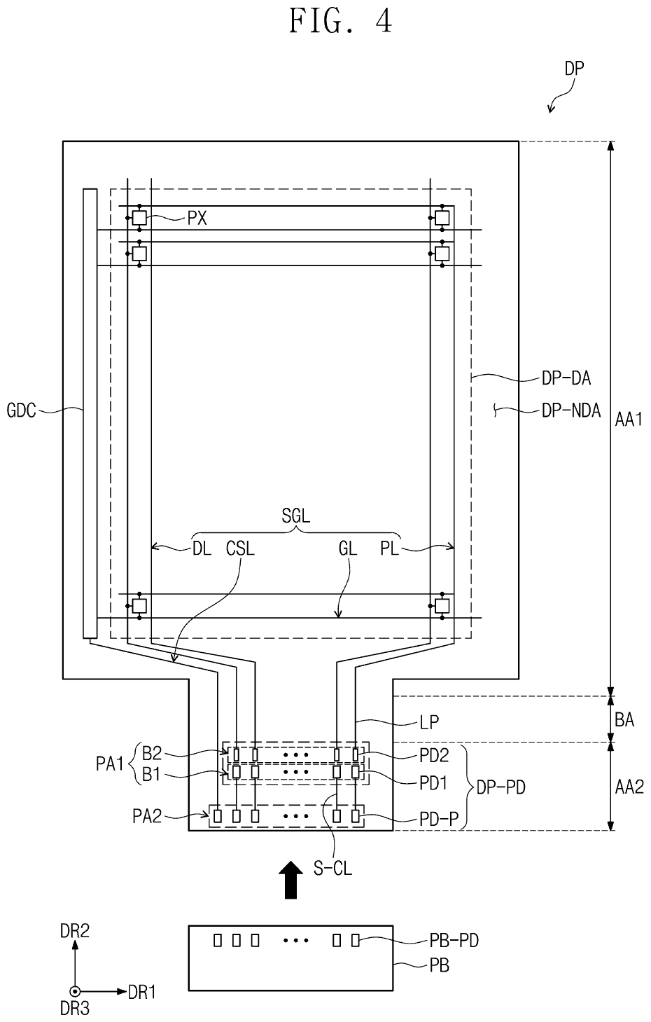

FIG. 4 is a plan view of the display panel according to an embodiment of the inventive concept. FIG. 4 illustrates a planar shape of the display panel DP illustrated in FIG. 3.

Referring to FIG. 4, the display panel DP may include a plurality of pixels PX, a gate driving circuit GDC, a plurality of signal lines SGL, and a plurality of pad electrodes DP-PD.

The display panel DP may include a first portion AA1, a second portion AA2, and a bent portion BA disposed between the first portion AA1 and the second portion AA2. The first portion AA1, the bent portion BA, and the second portion AA2 may be sequentially arranged along the second direction DR2. The bent portion BA may extend in the second direction DR2 from the first portion AA1, and the second portion AA2 may extend in the second direction DR2 from the bent portion BA.

The first portion AA1 may have long sides extending in the second direction DR2 and spaced apart from each other in the first direction DR1. A width of each of the bent portion BA and the second portion AA2 may be less than that of the first portion AA1 with respect to the first direction DR1.

The pixels PX may be disposed on the display area DP-DA. Each of the pixels PX may include an organic light emitting diode and a pixel driving circuit connected to the organic light emitting diode. The gate driving circuit GDC may sequentially output gate signals to a plurality of gate lines GL to be described later. The transistors of the gate driving circuit GDC may be formed through the same process as the transistors of the pixel PX such as a low temperature polycrystalline silicon (LTPS) process or a low temperature polycrystalline oxide (LTPO) process. The display panel DP may further include another driving circuit that provides emission control signals to the pixels PX.

The signal lines SGL may include gate lines GL, data lines DL, power lines PL, and control signal lines CSL. The gate lines GL may be respectively connected to corresponding pixels of the pixels PX, and the data lines DL may be respectively connected to corresponding pixels PX of the pixels PX. The power line PL may be connected to the pixels PX. The control signal line CSL may provide control signals to the scan driving circuit.

The signal lines SGL may overlap the display area DP-DA and the non-display area DP-NDA. Each of the signal lines SGL may include a line part LP. The line part LP may overlap the display area DP-DA and the non-display area DP-NDA.

The plurality of pad electrodes DP-PD may be disposed on the second portion AA2 of the non-display area DP-NDA. The plurality of pad electrodes DP-PD may include first pad electrodes PD1, second pad electrodes PD2, and substrate-side pad electrodes PD-P. An area on which the first and second pad electrodes PD1 and PD2 are disposed may be defined as a first pad area PA1, and an area on which the substrate-side pad electrodes PD-P are disposed may be defined as a second pad area PA2.

The first pad area PA1 may be an area overlapping the driver DC (see FIG. 6), and the second pad area PA2 may be an area overlapping the circuit board PB. The first pad area PA1 may include a first area B1 on which the first pad electrodes PD1 are disposed and a second area B2 on which the second pad electrodes PD2 are disposed. Each of the first pad electrodes PD1 may have a planar area greater than that of each of the second pad electrodes PD2. The first pad area PA1 and the second pad area PA2 may be disposed within the non-display area DP-NDA. The first pad area PA1 and the second pad area PA2 may be spaced apart from each other in the second direction DR2. The second pad area PA2 may be an area adjacent to the display area DP-DA compared to the first pad area PA1, and the first pad area PA1 may be an area spaced apart from the display area DP-DA with the second pad area PA2 therebetween.

Each of the second pad electrodes PD2 may be connected to a corresponding data line DL of the data lines DL. Although not shown, the first pad electrodes PD1 and the second pad electrodes PD2 may be electrically connected to each other. The first pad electrodes PD2 may be connected to the substrate-side pad electrodes PD-P through connection signal lines S-CL.

The circuit board PB may include a plurality of circuit pads PB-PD. The circuit pads PB-PD may be arranged in the first direction DR1. The circuit pads PB-PD of the circuit board PB may be connected to and in contact with substrate-side pad electrodes PD-P of the second pad area PA2.

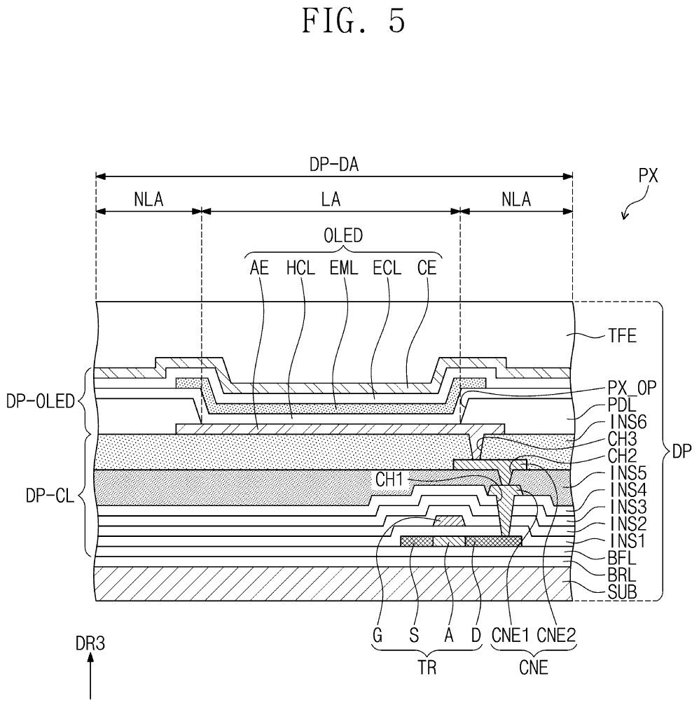

FIG. 5 is a cross-sectional view of the pixel according to an embodiment of the inventive concept.

Referring to FIGS. 4 and 5, the pixel PX may include a transistor TR and a light emitting element OLED. The light emitting element OLED may include a first electrode AE (or anode), a second electrode CE (or cathode), a hole control layer HCL, an electron control layer ECL, and an emission layer EML.

The transistor TR and the light emitting element OLED may be disposed on the substrate SUB. Although one transistor TR is illustrated as an example, in practice, the pixel PX may include a plurality of transistors and at least one capacitor for driving the light emitting element OLED. The plurality of transistors and at least one capacitor may be connected to each other.

The display area DP-DA may include an emission area LA corresponding to each pixel PX and a non-emission area NLA around the emission area LA. The light emitting element OLED may be disposed on the emission area LA.

The substrate SUB may include polyimide (PI) as a flexible plastic material. A barrier layer BRL may be disposed on the substrate SUB. A buffer layer BFL may be disposed on the barrier layer BRL. Each of the barrier layer BRL and the buffer layer BFL may be an inorganic layer.

A semiconductor pattern may be arranged on the buffer layer BFL. The semiconductor pattern may include polysilicon, amorphous silicon, or metal oxide. The semiconductor pattern may be doped with N-type dopants or P-type dopants. The semiconductor pattern may include a high-doped region and a low-doped region. The high-doped region may have conductivity greater than that of the low-doped region and may practically serve as source and drain electrodes of the transistor TR. The low-doped region may effectively correspond to an active (or channel) of the transistor.

A source S, an active A, and a drain D of the transistor TR may be provided from the semiconductor pattern. A first insulating layer INS1 may be arranged on the semiconductor pattern. A gate G of the transistor TR may be disposed on the first insulating layer INS1. A second insulating layer INS2 may be disposed on the gate G. A third insulating layer INS3 may be disposed on the second insulating layer INS2. A fourth insulating layer INS4 may be disposed on the third insulating layer INS3.

A connection electrode CNE may include a first connection electrode CNE1 and a second connection electrode CNE2 to connect the transistor TR and the light emitting element OLED. The first connection electrode CNE1 may be disposed on the fourth insulating layer INS4 and may be connected to the drain D through a first contact hole CH1 defined in the first to fourth insulating layers INS1 to INS4.

A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 through a second contact hole CH2 defined in the fifth insulating layers INS5.

A sixth insulating layer INS6 may be disposed on the second connection electrode CNE2. The layers from the buffer layer BFL to the sixth insulating layer INS6 may be defined as the circuit element layer DP-CL. Each of the first insulating layer INS1 to the sixth insulating layer INS6 may be an inorganic layer or an organic layer.

The first electrode AE may be disposed on the sixth insulating layer INS6. The first electrode AE may be connected to the second connection electrode CNE2 through the third contact hole CH3 defined in the sixth insulating layer INS6. The first electrode AE may be connected to the transistor TR via the first and second connection electrodes CNE1 and CNE2. A pixel defining layer PDL having an opening PX_OP defined therein to expose a predetermined portion of the first electrode AE may be disposed on the first electrode AE and the sixth insulating layer INS6.

The hole control layer HCL may be disposed on the first electrode AE and the pixel defining layer PDL. The hole control layer HCL may include a hole transport layer and a hole injection layer.

The emission layer EML may be disposed on the hole control layer HCL. The emission layer EML may be disposed on an area corresponding to the opening OP. The emission layer EML may include organic or inorganic materials. The emission layer EML may emit one of red light, green light, and blue light.

The electron control layer ECL may be disposed on the emission layer EML and the hole control layer HCL. The electron control layer ECL may include an electron transport layer and an electron injection layer. The hole control layer HCL and the electron control layer ECL may be commonly disposed on the light emitting region LA and the non-light emitting region NLA.

The second electrode CE may be disposed on the electronic control layer ECL. The second electrode CE may be commonly disposed on the pixels PX. The layer on which the light emitting element OLED is disposed may be defined as the display element layer DP-OLED.

The thin film encapsulation layer TFE may be disposed on the second electrode CE to cover the pixel PX (see FIG. 4). Although not shown, the thin film encapsulation TFE layer may be provided as a plurality of layers. Some of the plurality of layers may include an inorganic insulating layer and protect the pixel PX (see FIG. 4) from moisture/oxygen. The remaining some layers may include organic insulating layers and protect the pixels PX (see FIG. 4) from foreign substances such as dust particles.

A first voltage may be applied to the first electrode AE through the transistor TR, and a second voltage having a lower level than the first voltage may be applied to the second electrode CE. When holes and electrons injected into the emission layer EML are coupled to provide excitons, the light emitting element OLED may emit light when the excitons are transited to the ground state.

FIG. 6 is a side view of the display device according to an embodiment of the inventive concept. FIG. 6 is a view illustrating a state in which the bent portion BA is bent on the display panel DP of FIG. 4. FIG. 6 is a side view of the display device DD when viewed in the first direction DR1.

The substrate SUB, the circuit element layer DP-CL, the display element layer DP-OLED, and the thin film encapsulation layer TFE of FIG. 6 are identical to the substrate SUB, the circuit element layer DP-CL, the display element layer DP-OLED, and the thin film encapsulation layer TFE of FIG. 5, and thus, detailed descriptions will be omitted.

The display device DD may include a driver DC, a circuit board PB, a bending protection layer BPL, and a timing controller T-CON.

The driver DC may be disposed on the display panel DP and may be mounted on the display panel DP. However, this embodiment may not be limited thereto. For example, the driver DC may generate a driving signal that is required for an operation of the display panel DP based on a control signal transmitted from the circuit board PB.

The circuit board PB may be disposed on one end of the substrate SUB and may be electrically connected to the circuit element layer DP-CL. The timing controller T-CON may be disposed on the circuit board PB. The timing controller T-CON may be provided as a direct circuit chip and may be mounted on a top surface of the circuit board PB.

The bent portion BA may be bent so that the second portion AA2 is disposed below the first portion AA1. Thus, the driver DC, the circuit board PB, and the timing controller T-CON may be disposed below the second part AA2.

A bending protection layer BPL may be disposed on the bent portion BA. A bending protection layer BPL may be adjacent to edges of the first and second portions AA1 and AA2. The bending protection layer BPL may be disposed spaced apart from the thin film encapsulation layer TFE in the second direction DR2. The bending protection layer BPL may be bent together with the bent portion BA when the display panel DP is bent.

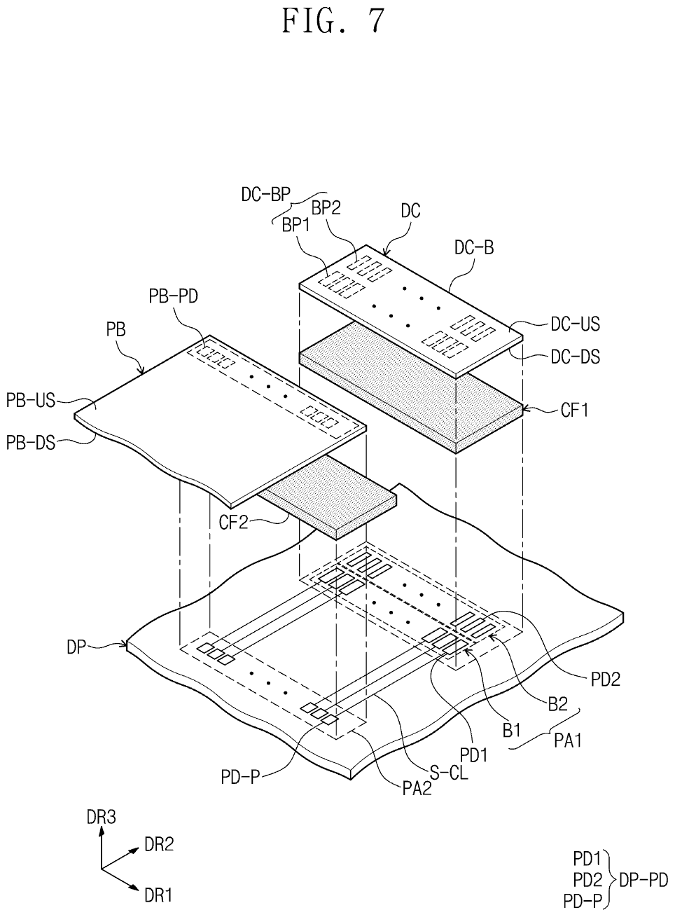

FIG. 7 is an enlarged perspective view illustrating a portion of the display device according to an embodiment of the inventive concept. In FIG. 7, the driver DC, the circuit board PB, and the display panel DP at the first and second pad areas PA1 and PA2 illustrated in FIG. 4 are enlarged and illustrated. For example, the driver DC and circuit board PB in FIG. 7 are shown as being disassembled from the display panel DP.

Referring to FIGS. 4 and 7, the driver DC may be bonded to the first pad area PA1 through the first adhesive layer CF1. The circuit board PB may be bonded to the second pad area PA2 through a second adhesive layer CF2.

Each of the first and second adhesive layers CF1 and CF2 may include a synthetic resin having adhesive properties. Each of the first and second adhesive layers CF1 and CF2 may include a non-conductive film. Each of the first and second adhesive layers CF1 and CF2 may not include conductive particles such as conductive balls and each of the first and second adhesive layers CF1 and CF2 may be made of a curable polymer material.

When the first adhesive layer CF1 is cured, the first and second pad electrodes PD1 and PD2 and the bump electrodes DC-BP may be fixed in a state of contact. When the second adhesive layer CF2 is cured, the substrate-side pad electrodes PD-P and the circuit pads PB-PD may be fixed in a state of contact.

The first pad area PA1 of the display panel DP may overlap the driver DC, and the second pad area PA2 may overlap the circuit board PB. The first pad area PA1 may include a first area B1 on which the first pad electrodes PD1 are disposed and a second area B2 on which the second pad electrodes PD2 are disposed. Each of the first pad electrodes PD1 may have a planar area greater than that of each of the second pad electrodes PD2. The first pad area PA1 and the second pad area PA2 may be disposed within the non-display area DP-NDA. The first pad area PA1 and the second pad area PA2 may be spaced apart from each other in the second direction DR2.

The driver DC may be disposed on the first and second pad electrodes PD1 and PD2. The driver DC may include a driver-integrated circuit DC-B, and the driver-integrated circuit DC-B may include a top surface DC-US and a bottom surface DC-DS. The bottom surface DC-DS of the driver DC may be a surface facing the first and second pad electrodes PD1 and PD2. The driver DC may include bump electrodes DC-BP electrically connected to the first pad electrodes PD1 disposed on the substrate SUB. The bump electrodes DC-BP may be disposed on the bottom surface DC-DS of the driver-integrated circuit DC-B. The bottom surface DC-DS of the driver-integrated circuit DC-B may be a base surface on which the bump electrodes DC-BP are provided. The bump electrodes DC-BP may be disposed to correspond to the pad electrodes PD1 and PD2.

The bump electrodes DC-BP may include first bump electrodes BP1 and second bump electrodes BP2. Each of the first bump electrodes BP1 may have a planar area greater than that of each of the second bump electrodes BP2. The first bump electrodes BP1 and the second bump electrodes BP2 may be spaced apart from each other in the second direction DR2. The first bump electrodes BP1 may be arranged in the first direction DR1. The second bump electrodes BP2 may be arranged in the first direction DR1. In FIG. 7, for convenience of explanation, a planar shape of each of the bump electrodes DC-BP may be illustrated with a dotted line on the top surface DC-US of the driver DC, but each of the first bump electrodes BP1 and the second bump electrodes BP2 may have a shape that protrudes from the bottom surface DC-DS of the driver DC and is exposed to the outside.

When the driver DC is bonded to the display panel DP by the first adhesive layer CF1, at least a portion of each of the first bump electrodes BPI may be electrically connected by being in contact with the first pad electrodes PD1, and at least a portion of each of the second bump electrodes BP2 may be electrically connected by being in contact with the second pad electrodes PD2. The second bump electrodes BP2 may be disposed adjacent to the display area DP-DA (see FIG. 4) compared to the first bump electrodes BP1, and the first bump electrodes BP1 may be disposed spaced apart from the display area DP-DA (see FIG. 4) with the second bump electrodes BP2 therebetween.

The driver DC may include the driver-integrated circuit DC-B. The driver-integrated circuit DC-B may be disposed on the bump electrodes DC-BP. The driver-integrated circuit DC-B may be connected to the bump electrodes DC-BP. The driver DC may receive first signals from the outside through the first pad electrodes PD1 and the first bump electrodes BP1. The driver DC may provide second signals generated based on the signals to the second pad electrodes PD2 through the second bump electrodes BP2. The first signal may be a video signal, which is a digital signal applied from the outside, and the second signal may be a data signal, which is an analog signal. The driver DC may generate an analog voltage corresponding to a grayscale value of the image signal. A data signal may be provided to the pixel PX through the data line DL as illustrated in FIG. 4.

The circuit board PB may be disposed on the display panel DP. The circuit board PB may be disposed on the substrate-side pad electrodes PD-P. The circuit board PB may include a top surface PB-US and a bottom surface PB-DS. The bottom surface PB-DS of the circuit board PB may be a surface facing the substrate-side pad electrodes PD-P. The circuit board PB may include a plurality of circuit pads PB-PD electrically connected to substrate-side pad electrodes PD-P. The circuit pads PB-PD may be disposed on the bottom surface PB-DS of the circuit board PB. The circuit pads PB-PD may be arranged in the first direction DR1. The circuit board PB may provide image signals, driving voltages, and other control signals to the driver DC.

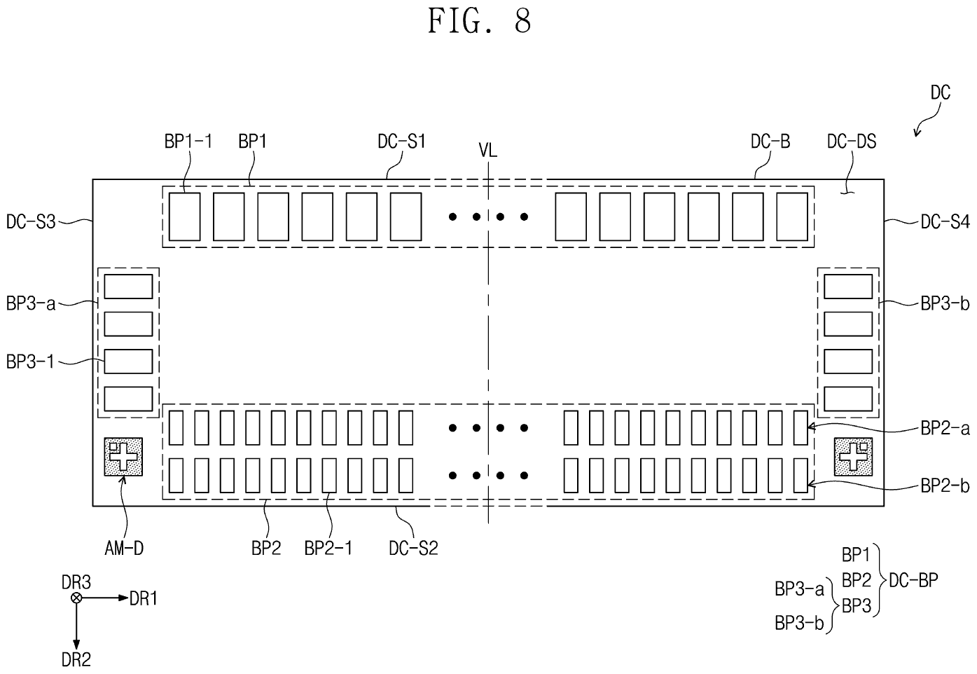

Hereinafter, a specific arrangement of the plurality of bump electrodes of the driver and a connection shape with the pad electrodes will be described with reference to FIG. 8, etc.

FIG. 8 is a plan view of the driver DC according to an embodiment of the inventive concept. FIG. 8 illustrates an arrangement of the bump electrodes DC-BP disposed on the bottom surface DC-DS of the driver-integrated circuit DC-B.

Referring to FIGS. 7 and 8, the driver DC may include the driver-integrated circuit DC-B and the plurality of bump electrodes DC-BP disposed on the bottom surface DC-DS of the driver-integrated circuit DC-B. The bump electrodes DC-BP may include a plurality of first bump electrodes BP1 and a plurality of second bump electrodes BP2.

Each of the plurality of first bump electrodes BPI and each of the plurality of second bump electrodes BP2 may be arranged in the first direction DR1. The first bump electrodes BP1 and the second bump electrodes BP2 may be spaced apart from each other in the second direction DR2.

The driver DC may include two long sides DC-S1 and DC-S2 extending in the first direction DR1 and two short sides DC-S3 and DC-S4 extending in the second direction DR2, and the first bump electrodes BP1 and the second bump electrodes BP2 may be disposed adjacent to the long sides DC-S1 and DC-S2. The first bump electrodes BP1 may be disposed adjacent to the first long side DC-S1, and the second bump electrodes BP2 may be disposed adjacent to the second long side DC-S2. In a state in which the driver DC is bonded to the display panel DP, the second long side DC-S2 may be a long side disposed adjacent to the above-described display area DP-DA (see FIG. 4), and the first long side DC-S1 may be a long side spaced apart from the display area DP-DA (see FIG. 4) with the second long side DC-S2 therebetween.

Each of the first bump electrodes BP1 may have a planar area greater than that of each of the second bump electrodes BP2. Each of the first bump electrodes BP1 and the second bump electrodes BP2 may have a rectangular shape on a plane. Each of the first bump electrodes BP1 may have a rectangular shape having a planar area greater than that of each of the second bump electrodes BP2.

At least one of the first bump electrodes BP1 or the second bump electrodes BP2 may have a plurality of bump rows. In the driver DC according to an embodiment, the second bump electrodes BP2 may have two bump rows. Each of the second bump electrodes BP2 may include a first row BP2-a and a second row BP2-b, which extend in the first direction DR1. Unlike as illustrated in FIG. 8, each of the second bump electrodes BP2 may have only one bump row or may have three or more bump rows. In addition, the first bump electrodes BP1 may have a plurality of bump rows.

The bump electrodes DC-BP may further include a plurality of third bump electrodes BP3. The plurality of third bump electrodes BP3 may be disposed adjacent to the short sides DC-S3 and DC-S4 of the driver DC. The third bump electrodes BP3 may include left bump electrodes BP3-a disposed adjacent to the first short side DC-S3 and right bump electrodes BP3-b disposed adjacent to the second short side DC-S4. Each of the left bump electrodes BP3-a and the right bump electrodes BP3-b may be arranged along the second direction DR2. The left bump electrodes BP3-a and the right bump electrodes BP3-b may be spaced apart from each other in the first direction DR1.

The number of plurality of first bump electrodes BP1 and the number of plurality of second bump electrodes BP2, which are included in the driver DC, may be different from each other. In the driver DC according to an embodiment, the number of first bump electrodes BP1, each of which has a larger planar area, may be included in smaller number compared to the number of second bump electrodes BP2, each of which has a relatively small planar area. The number of plurality of second bump electrodes BP2 included in the driver DC may be greater than each of the number of plurality of first bump electrodes BPI and the number of plurality of third bump electrodes BP3.

The driver DC may have a symmetrical shape with respect to a reference line VL extending in the second direction DR2. The reference line VL may extend in the second direction DR2 and may extend to cross a center of each of the two long sides DC-S1 and DC-S2 of the driver DC. Each of the bump electrodes DC-BP included in the driver DC may be arranged to have a symmetrical shape with respect to the reference line VL. Each of the first bump electrodes BP1 and the second bump electrodes BP2 may be arranged along the first direction DR1 and may be arranged symmetrically with respect to the reference line VL. Each of the left bump electrodes BP3-a and the right bump electrodes BP3-b included in the third bump electrodes BP3 may be arranged along the second direction DR2, and the left bump electrodes BP3-a may be arranged to be symmetrical to the right bump electrodes BP3-b with respect to the reference line VL.

The driver DC may further include an alignment mark AM-D adjacent to at least one of the bump electrodes DC-BP in one direction. The alignment mark AM-D may, for example, be adjacent to the second bump electrodes BP2 in the first direction DR1 and be adjacent to the third bump electrodes BP3 in the second direction DR2. The alignment mark AM-D may be applied as an identification mark to identify a position of the driver DC or to align the driver DC with the display panel DP in the process of bonding the driver DC to the display panel DP. In FIG. 8, the alignment mark AM-D is illustrated as including a cross shape and a square shape as an example, but is not limited thereto, and the alignment mark AM-D may be provided in various shapes as long as it is for the purpose of aligning each configuration.

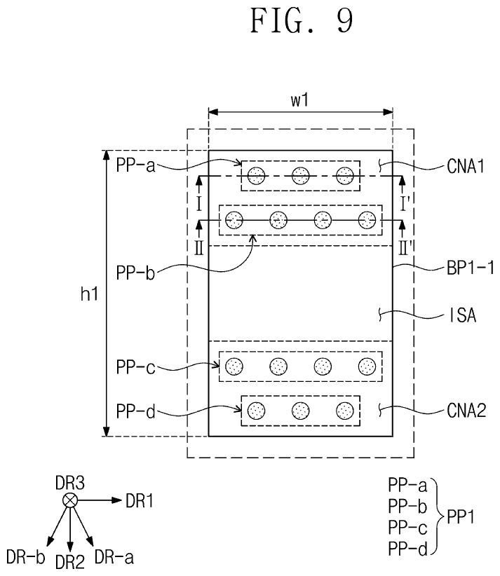

FIG. 9 is a plan view illustrating one of the first bump electrodes included in the driver according to an embodiment of the inventive concept. In FIG. 9, one first bump electrode BP1-1 of the plurality of first bump electrodes BP1 illustrated in FIG. 8 is enlarged and illustrated. In FIG. 9 and below, an arrangement and shape of a protrusion member included in one first bump electrode BP1-1 is illustrated, but similar descriptions may be applied to the second bump electrode BP2-1 and the third bump electrode BP3-1 illustrated in FIG. 8 in addition to the first bump electrode BP1-1.

Referring to FIGS. 8 and 9 together, the first bump electrode BP1-1 may have a planar area greater than that of the second bump electrode BP2-1. The first bump electrode BP1-1 may have a first width w1 in the first direction DR1, a first length h1 in the second direction DR2, and a first surface area on the plane. The first surface area may be, for example, greater than or equal to about 500 μm² and less than or equal to about 1,500 μm².

Each of the first bump electrode BP1-1, the second bump electrodes BP2-1, and the third bump electrode BP3-1, which are included in the plurality of bump electrodes DC-BP, may include a plurality of protrusion members. The first bump electrode BP1-1 may include a plurality of first protrusion members PP1.

In an embodiment, the first protrusion members PP1 included in the first bump electrode BP1-1 may have a circular shape on the plane, and the widths of the first protrusion members PP1 may be substantially the same. Each of the first protrusion members PP1 included in the first bump electrode BP1-1 may have a first pattern width d1, and the first pattern widths d1 of the first protrusion members PP1 may be substantially the same as each other. In this specification, the width being “substantially the same” includes not only a case in which the width of the patterns are physically the same, but also a case in which there is a difference equivalent to an error that occurs during a manufacturing process.

The first protrusion members PP1 included in the first bump electrode BP1-1 may be provided in a plurality of rows. The first protrusion members PP1 may include first row protrusion members PP-a arranged along the first direction DR1 and second row protrusion members PP-b arranged along the first direction DR1. Each of the first row protrusion member PP-a and the second row protrusion member PP-b may be disposed on a first contact area CNA1 of the first bump electrode BP1-1. The first row protrusion member PP-a may be spaced apart from the second row protrusion member PP-b in the second direction DR2.

Each of the first row protrusion members PP-a and the second row protrusion members PP-b may be provided in plurality, and each of the plurality of first row protrusion members PP-a and the plurality of second row protrusion members PP-b may be arranged along the first direction DR1.

At least some of the plurality of first row protrusion members PP-a and the plurality of second row protrusion members PP-b may be disposed alternately to not align with each other in the second direction DR2. In an embodiment, each of the plurality of first row protrusion members PP-a and each of the plurality of second row protrusion members PP-b may not align with each other in the second direction DR2, as illustrated in FIG. 9. The plurality of first row protrusion members PP-a may be disposed to be spaced apart from each other in diagonal directions DR-a and DR-b with respect to the plurality of second row protrusion members PP-b. In an embodiment, the diagonal directions DR-a and DR-b may correspond to directions between the first direction DR1 and the second direction DR2, respectively. That is, the plurality of first row protrusion members PP-a and the plurality of second row protrusion members PP-b may be arranged in a zigzag shape with the diagonal directions DR-a and DR-b as the progressing direction, as illustrated in FIG. 9.

The number of plurality of first row protrusion members PP-a and the number of plurality of second row protrusion members PP-b, which are included in the first protrusion members PP1, may be different from each other. In an embodiment, the number of plurality of second row protrusion members PP-b may be greater than the number of plurality of first row protrusion members PP-a. In FIG. 9, the first bump electrode BP1-1 is illustrated as including three first row protrusion members PP-a and four second row protrusion members PP-b, but the number of first row protrusion members PP-a and the number of second row protrusion members PP-b may be variously changed within a range for securing the electrical connection characteristics between the bump electrodes and the pad electrodes.

The first protrusion members PP1 included in the first bump electrode BP1-1 may include third row protrusion members PP-c arranged along the first direction DR1, and fourth row protrusion members PP-d arranged along the first direction DR1. Each of the third row protrusion member PP-c and the fourth row protrusion member PP-d may be disposed in a second contact area CNA2 of the first bump electrode BP1-1. The third row protrusion member PP-c may be spaced apart from the fourth row protrusion member PP-d in the second direction DR2.

Each of the third row protrusion members PP-c and the fourth row protrusion members PP-d may be provided in plurality, and each of the plurality of third row protrusion members PP-c and the plurality of fourth row protrusion members PP-d may be arranged along the first direction DR1.

At least some of the plurality of third row protrusion members PP-c and the plurality of fourth row protrusion members PP-d may be arranged alternately to not align with each other in the second direction DR2. In an embodiment, each of the plurality of third row protrusion members PP-c and each of the plurality of fourth row protrusion members PP-d may not align with each other in the second direction DR2, as illustrated in FIG. 9. Each of the plurality of third row protrusion members PP-c may be disposed to be spaced apart from each other in the diagonal directions DR-a and DR-b with respect to each of the plurality of fourth row protrusion members PP-d. That is, the plurality of third row protrusion members PP-c and the plurality of fourth row protrusion members PP-d may be arranged in a zigzag shape with the diagonal directions DR-a and DR-b as the progressing direction, as illustrated in FIG. 9.

The number of plurality of third row protrusion members PP-c and the number of plurality of fourth row protrusion members PP-d, which are included in the first protrusion members PP1, may be different from each other. In an embodiment, the number of plurality of third row protrusion members PP-c may be greater than the number of plurality of fourth row protrusion members PP-d. In FIG. 9, the first bump electrode BP1-1 is illustrated as including four third row protrusion members PP-c and three fourth row protrusion members PP-d, but the number of third row protrusion members PP-c and the number of fourth row protrusion members PP-d may be variously changed within a range for securing the electrical connection characteristics between the bump electrodes and the pad electrodes.

In the first bump electrode BP1-1, an inspection area ISA may be provided between the first contact area CNA1 and the second contact area CNA2. The first protrusion members PP1 may not be disposed on the inspection area ISA. The inspection area ISA may be an area, on which an electrical operation test of the first bump electrode BP1-1 is performed, and also may be an area on which the first protrusion members PP1 are not provided to perform the electrical operation test.

In the first bump electrode BP1-1, the first protrusion members PP1 disposed on the first connection area CNA1 and the first protrusion members PP1 disposed on the second connection area CNA2 may be arranged in a symmetrical shape with respect to the inspection area ISA. The first row protrusion member PP-a disposed on the first connection area CNA1 may be arranged to be symmetrical to the fourth row protrusion member PP-d disposed on the second connection area CNA2. The second row protrusion member PP-b disposed on the first connection area CNA1 may be arranged to be symmetrical to the third row protrusion member PP-c disposed on the second connection area CNA2. At least some of the first row protrusion members PP-a and the fourth row protrusion members PP-d may be arranged parallel to each other in the second direction DR2. At least some of the second row protrusion members PP-b and the third row protrusion members PP-c may be arranged parallel to each other in the second direction DR2.

In an embodiment, a predetermined proportional relationship may be established between a total area of the first bump electrode BP1-1, which is one of the plurality of bump electrodes DC-BP, and a total area of the first protrusion members PPI included in the corresponding first bump electrode BP1-1. In an embodiment, the total area of the first bump electrode BP1-1 and the total area of the first protrusion members PPI may satisfy following Equation 1.

0.0012≤B/A≤0.0146 [Equation 1]

In Equation 1, reference symbol A may correspond to a surface area of one first bump electrode BP1-1. Reference symbol B may correspond to the total area of the first protrusion members PP1 included in one first bump electrode BP1-1. That is, the B may correspond to a product of a surface area of each of the first protrusion members PP1 included in one first bump electrode BP1-1 and the number of first protrusion members PP1 included in one first bump electrode BP1-1. In Equation 1, if a B/A value is less than about 0.0012, when an alignment mismatch occurs between the first bump electrode BP1-1 and the corresponding pad electrode when the driver and the display panel are bonded, a sufficient contact area may not be secured between the first bump electrode BP1-1 and the corresponding pad electrode. In Equation 1, if the B/A value exceeds about 0.0146, when the driver and the display panel are bonded, the pressure applied by each of the plurality of first protrusion members included in the first bump electrode BP1-1 may be insufficient, which may cause contact failure between the bump electrode and the pad electrode, and thus, resistance may increase between the first bump electrode BP1-1 and the corresponding pad electrode to cause electrical connection failure.

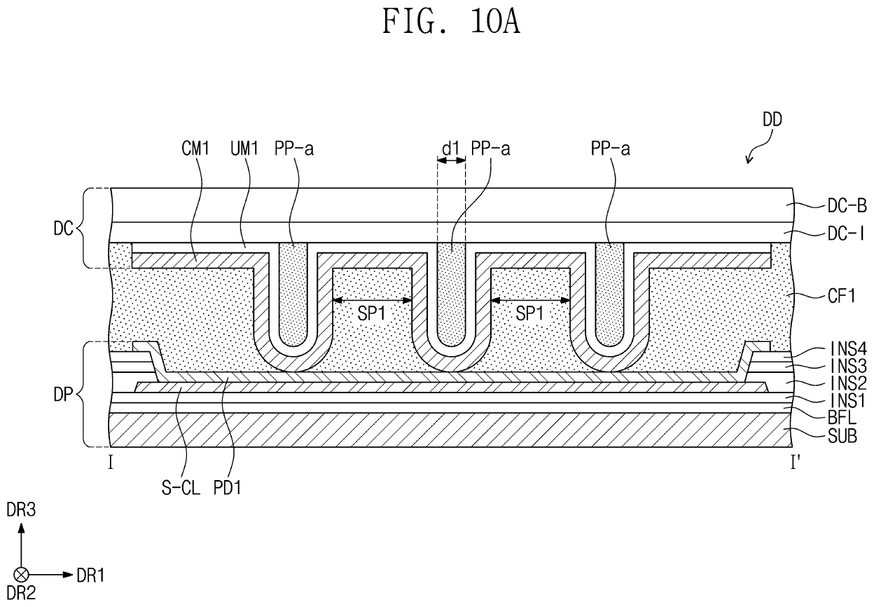

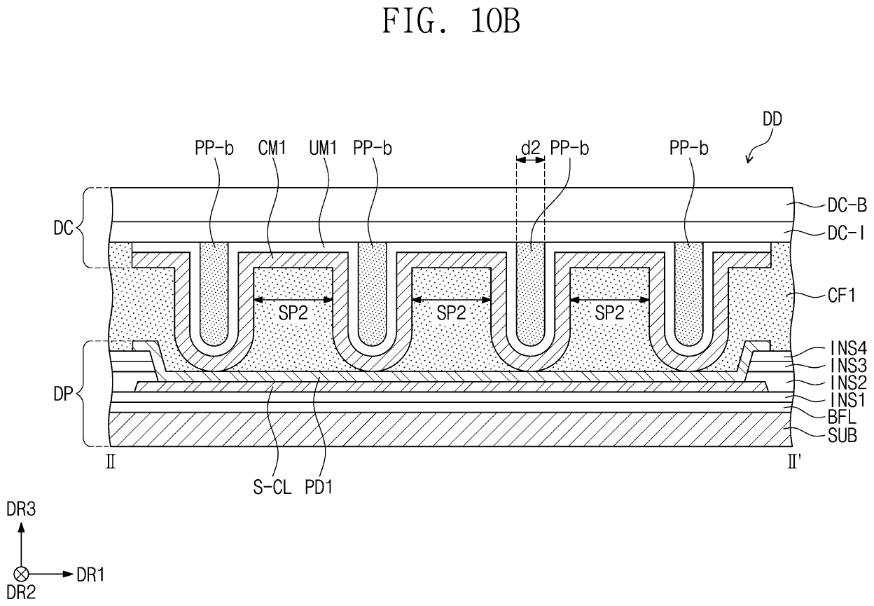

FIGS. 10A and 10B are cross-sectional views illustrating a portion of the display device according to an embodiment of the inventive concept. FIG. 10A illustrates a cross-sectional view of the display device DD, taken along line I-I′ of FIG. 9. FIG. 10B illustrates a cross-sectional view of the display device DD, taken along line II-II′ of FIG. 9.

Referring to FIGS. 8, 9, and 10A and 10B together, the display device DD according to an embodiment may include the display panel DP and the driver DC, and the display panel DP and the driver DC may be bonded through a first adhesive layer CF1. The first adhesive layer CF1 may include a synthetic resin having adhesive properties. The first adhesive layer CF1 may include a non-conductive film. The first adhesive layer CF1 may not include conductive particles such as conductive balls and may be made of a curable polymer material.

The display panel DP may include a substrate SUB, a plurality of insulating layers BFL, INS1, INS2, INS3, and INS4 disposed on the substrate SUB, and a pad electrode PD1. The pad electrode PD1 may be electrically connected to corresponding signal lines. In an embodiment, the pad electrode PD1 may be electrically connected to the connection signal line S-CL.

The driver DC may include a driver-integrated circuit DC-B and a first bump electrode BP1 disposed below the driver-integrated circuit DC-B. The first bump electrode BP1 may include a plurality of first protrusion members PP1 and a first bonding layer CM1.

The driver DC may further include a driver-insulating layer DC-I disposed below the driver-integrated circuit DC-B. The driver-insulating layer DC-I may include an insulating material. The driver-insulating layer DC-I may be an inorganic or organic layer.

Although not shown, the driver DC may further include a driving pad disposed below the driver-integrated circuit DC-B. The driver-insulating layer DC-I may expose a portion of a bottom surface of the driving pad and cover a remaining portion. The driving pad may be disposed on the bottom surface DC-DS of the driver-integrated circuit DC-B. The driving pad may be electrically connected to the first bump electrode BP1 to transmit signals provided from the driver-integrated circuit DC-B to the first bump electrode BP1 or transmit signals provided from the first bump electrode BPI to the driver-integrated circuit DC-B. The driving pad may include a first driving pad to which the first bump electrode BPI is electrically connected. The driving pad may be disposed, for example, on the inspection area ISA described above.

The plurality of first protrusion members PPI included in the first bump electrode BP1 may protrude from the bottom surface DC-DS of the driver-integrated circuit DC-B in a direction adjacent to the display panel DP. Each of the plurality of first protrusion members PP1 may include a polymeric material. Each of the plurality of first protrusion members PP1 may include, for example, polyimide.

Each of the plurality of first protrusion members PP1 may have a circular shape on the plane. Each of the plurality of first protrusion members PP1 may have a shape of which a width decreases as it approaches the display panel DP. Each of the plurality of first protrusion members PP1 may have a cylindrical shape with a rounded bottom surface provided adjacent to the display panel DP, as illustrated in FIGS. 10A and 10B, and thus may have a shape of which a width decreases as it approaches the display panel DP. However, this embodiment is not limited thereto, and each of the plurality of first protrusion members PP1 may have a cone shape of which a width decreases as it approaches the display panel DP.

A first bonding layer CM1 included in the first bump electrode BP1 may be disposed below the plurality of first protrusion members PP1 to cover each of the plurality of first protrusion members PP1. The first bonding layer CM1 may include a conductive metal. The first bonding layer CM1 may include, for example, any one selected from gold (Au), copper (Cu), tin (Sn), a gold-tin alloy (Au/Sn), a tin-silver alloy (Sn/Ag), indium (In), a bismuth-tin alloy (Bi/Sn), and a tin-lead alloy (Sn/Pb).

In the display device DD according to an embodiment, the first bonding layer CM1 may be in contact with a corresponding first pad electrode PD1. The first bonding layer CM1 included in one first bump electrode BP1 may be in contact with a corresponding one first pad electrode PD1.

The first bump electrode BP1 may further include a first intermediate layer UM1. The first intermediate layer UM1 may be disposed between the first protrusion member PP1 and the first bonding layer CM1. The first intermediate layer UM1 may cover an outer surface of each of the plurality of first protrusion members PP1. Although not shown, the first intermediate layer UM1 may be electrically connected to the driving pad of the driver DC. The first intermediate layer UM1 may include a conductive metal. The first intermediate layer UM1 may include, for example, any one selected from titanium (Ti), titanium-tungsten (TiW), copper (Cu), nickel (Ni), gold (Au), and nickel-vanadium (NiV).

The first protrusion members PP1 included in the first bump electrode BP1-1 may be provided in a plurality of rows. The first protrusion members PP1 include the first row protrusion members PP-a illustrated in FIG. 10A and the second row protrusion members PP-b illustrated in FIG. 10B. Each of the first row protrusion members PP-a and the second row protrusion members PP-b may be provided in plurality, and each of the plurality of first row protrusion members PP-a and the plurality of second row protrusion members PP-b may be arranged along the first direction DR1. The first row protrusion member PP-a may be spaced apart from the second row protrusion member PP-b in the second direction DR2.

Each of the first row protrusion member PP-a and the second row protrusion member PP-b may be covered by the first bonding layer CM1. The first intermediate layer UM1 may be disposed between each of the first row protrusion member PP-a and the second row protrusion member PP-b and the first bonding layer CM1. The first intermediate layer UM1 may cover an outer surface of each of the first row protrusion members PP-a and the second row protrusion members PP-b.

At least some of the plurality of first row protrusion members PP-a and the plurality of second row protrusion members PP-b may be disposed alternately to not align with each other in the second direction DR2. In an embodiment, a first spacer SP1 may be provided between the plurality of first row protrusion members PP-a, and a second spacer SP2 may be provided between the plurality of second row protrusion members PP-b. In the second direction DR2, at least some of the plurality of first row protrusion members PP-a may be provided to align with the second spacer SP2. In the second direction DR2, at least some of the plurality of second row protrusion members PP-b may be provided to align with the first spacer SP1.

Each of the plurality of first row protrusion members PP-a and each of the plurality of second row protrusion members PP-b, which are included in the first protrusion member PP1, may have substantially the same planar shape and width. Each of the plurality of first row protrusion members PP-a and the plurality of second row protrusion members PP-b may have a circular shape on the plane. Each of the plurality of first row protrusion members PP-a may have a first pattern width d1 along the first direction DR1, and each of the plurality of second row protrusion members PP-b may have a second pattern width d2 along the first direction DR1. Here, the first pattern width d1 and the second pattern width d2 may be substantially the same. Although not specifically shown, the shape and pattern width of each of the plurality of third row protrusion members PP-c and the plurality of fourth row protrusion members PP-d may also be substantially the same as the shape and pattern width of each of the plurality of first row protrusion members PP-a and the plurality of second row protrusion members PP-b.

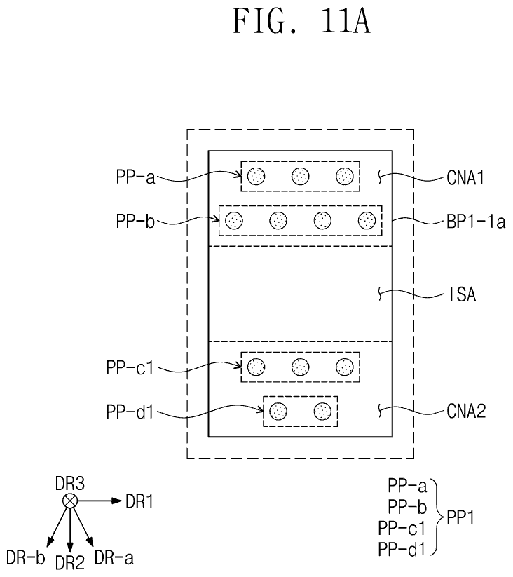

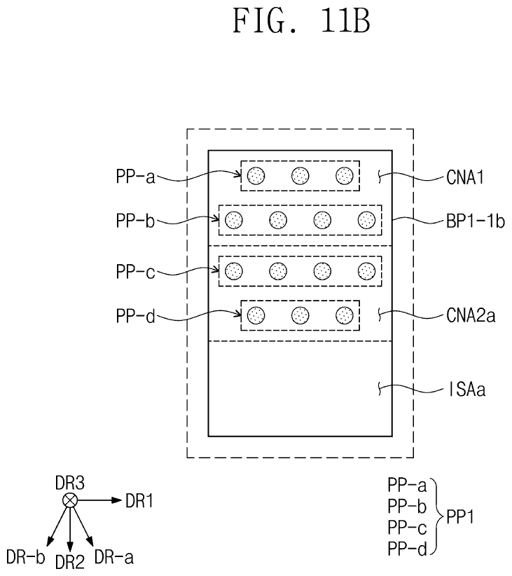

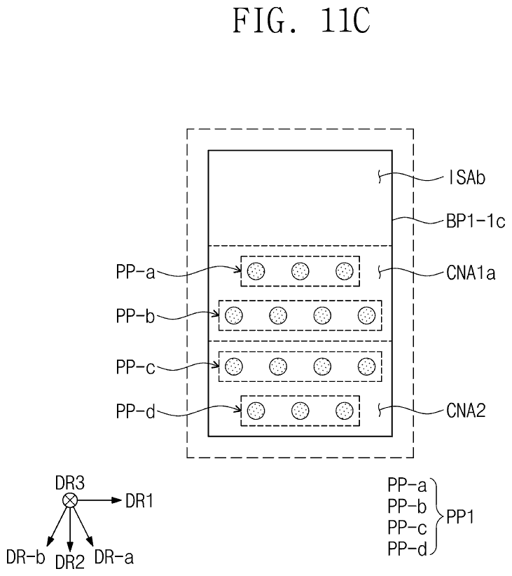

FIGS. 11A to 11C are plan views illustrating one of the first bump electrodes included in the driver according to an embodiment of the inventive concept. FIGS. 11a to 11c illustrate a planar shape of the first bump electrodes BP1-1 illustrated in FIG. 9 and a planar shape of the first bump electrodes BP1-1a, BP1-1b, and BP1-1c) according to another embodiment, respectively.

Referring to FIG. 11A, the first protrusion members PP1 included in the first bump electrode BP1-1a may be provided in plurality of rows. The first protrusion members PP1 may include first row protrusion members PP-a, second row protrusion members PP-b, third row protrusion members PP-c1, and fourth row protrusion members PP-d1. Each of the first row protrusion members PP-a, the second row protrusion members PP-b, the third row protrusion members PP-c1, and the fourth row protrusion members PP-d1 may be provided in plurality, and each of the plurality of first row protrusion members PP-a, each of the plurality of second row protrusion members PP-b, each of the plurality of third row protrusion members PP-c1, and each of the plurality of fourth row protrusion members PP-d1 may be arranged along the first direction DR1. The first row protrusion member PP-a and the second row protrusion member PP-b may be disposed on the first connection area CNA1 of the first bump electrode BP1-1, and the third row protrusion member PP-c1 and the fourth row protrusion member PP-d1 may be disposed on the second connection area CNA2 of the first bump electrode BP1-1. The first row protrusion member PP-a, the second row protrusion members PP-b, the third row protrusion members PP-c1, and the fourth row protrusion members PP-d1 may be spaced apart from each other in the second direction DR2.

At least some of the plurality of first row protrusion members PP-a and the plurality of second row protrusion members PP-b may be disposed alternately to not align with each other in the second direction DR2. In an embodiment, each of the plurality of first row protrusion members PP-a and each of the plurality of second row protrusion members PP-b may not align with each other in the second direction DR2, as illustrated in FIG. 11A. The plurality of first row protrusion members PP-a may be disposed to be spaced apart from each other in diagonal directions DR-a and DR-b with respect to the plurality of second row protrusion members PP-b, respectively. The plurality of first row protrusion members PP-a and the plurality of second row protrusion members PP-b may be arranged in a zigzag shape with the diagonal directions DR-a and DR-b as the progressing direction, as illustrated in FIG. 11A.

At least some of the plurality of third row protrusion members PP-c1 and the plurality of fourth row protrusion members PP-d1 may be arranged alternately to not align with each other in the second direction DR2. In an embodiment, each of the plurality of third row protrusion members PP-c1 and each of the plurality of fourth row protrusion members PP-d1 may not align with each other in the second direction DR2, as illustrated in FIG. 11A. Each of the plurality of third row protrusion members PP-c1 may be disposed to be spaced apart from each other in the diagonal directions DR-a and DR-b with respect to each of the plurality of fourth row protrusion members PP-d1. The plurality of third row protrusion members PP-c1 and the plurality of fourth row protrusion members PP-d1 may be arranged in a zigzag shape with the diagonal directions DR-a and DR-b as the progressing direction, as illustrated in FIG. 11A.

The number of plurality of first row protrusion members PP-a and the number of plurality of second row protrusion members PP-b, which are included in the first protrusion members PP1, may be different from each other. In an embodiment, the number of plurality of second row protrusion members PP-b may be greater than the number of plurality of first row protrusion members PP-a.

The number of plurality of third row protrusion members PP-c1 and the number of plurality of fourth row protrusion members PP-d1, which are included in the first protrusion members PP1, may be different from each other. In an embodiment, the number of plurality of third row protrusion members PP-c1 may be greater than the number of plurality of fourth row protrusion members PP-d1. In FIG. 11A, the first bump electrode BP1-1a is illustrated as including three third row protrusion members PP-c1 and two fourth row protrusion members PP-d1, but the number of third row protrusion members PP-c1 and the number of fourth row protrusion members PP-d1 may be variously changed within a range for securing the electrical connection characteristics between the bump electrode and the pad electrode.

In the first bump electrode BP1-1a, the number of first protrusion members PP1 disposed on the first connection area CNA1 and the number of first protrusion members PP1 disposed on the second connection area CNA2 may be different from each other. In an embodiment, the number of first protrusion members PP1 disposed on the first connection area CNA1 may be greater than the number of first protrusion members PP1 disposed on the second connection area CNA2. That is, the sum of the number of first row protrusion members PP-a and the number of second row protrusion members PP-b in the first bump electrode BP1-1a may be greater than the sum of the number of third row protrusion members PP-c1 and the number of fourth row protrusion members PP-d1. Unlike as shown in FIG. 11A, the sum of the number of first row protrusion members PP-a and the number of second row protrusion members PP-b in the first bump electrode BP1-1a may be less than the sum of the number of third row protrusion members PP-c1 and the number of fourth row protrusion members PP-d1.

At least some of the first row protrusion members PP-a disposed on the first connection area CNA1 and the third row protrusion members PP-c1 disposed on the second connection area CNA2 may be arranged parallel to each other in the second direction DR2. At least some of the second row protrusion members PP-b disposed on the first connection area CNA1 and the fourth row protrusion members PP-d1 disposed on the second connection area CNA2 may be arranged parallel to each other in the second direction DR2.

FIGS. 11B and 11C illustrate first bump electrodes BP1-1b and BP1-1c according to an embodiment, unlike the first bump electrode BP1-1 illustrated in FIG. 9, in which inspection areas ISAa and ISAb are disposed at one side of the connection areas rather than between the connection areas.

Referring to FIG. 11B, in the first bump electrode BP1-1b, the first row protrusion member PP-a and the second row protrusion member PP-b may be disposed on the first connection area CNA1 of the first bump electrode BP1-1b, and the third row protrusion member PP-c and the fourth row protrusion member PP-d may be disposed on the second connection area CNA2 of the first bump electrode BP1-1b. The inspection area ISAa may be disposed at one side of the second connection area CNA2a and may be spaced apart from the first connection area CNA1 with the second connection area CNA2a therebetween. The first protrusion members PP1 may not be disposed on the inspection area ISA. The inspection area ISA may be an area, on which an electrical operation test of the first bump electrode BP1-1b is performed, and also may be an area on which the first protrusion members PP1 are not provided to perform the electrical operation test.

Referring to FIG. 11C, in the first bump electrode BP1-1c, the first row protrusion member PP-a and the second row protrusion member PP-b may be disposed on the first connection area CNA1 of the first bump electrode BP1-1c, and the third row protrusion member PP-c and the fourth row protrusion member PP-d may be disposed on the second connection area CNA2 of the first bump electrode BP1-1c. The inspection area ISAb may be disposed at one side of the first connection area CNA1a and may be spaced apart from the second connection area CNA2 with the first connection area CNA1a therebetween. The first protrusion members PP1 may not be disposed on the inspection area ISA. The inspection area ISA may be an area, on which an electrical operation test of the first bump electrode BP1-1c is performed, and also may be an area on which the first protrusion members PP1 are not provided to perform the electrical operation test.

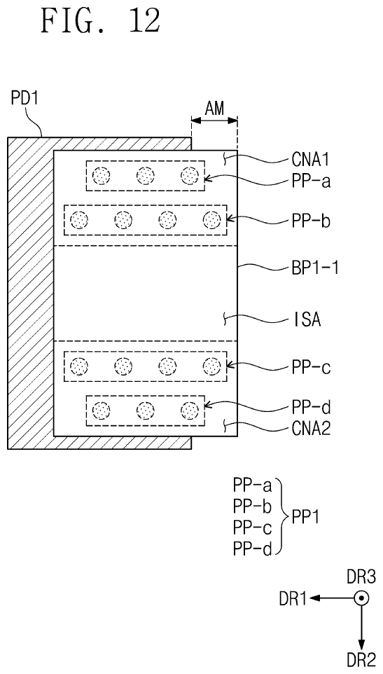

FIG. 12 is a plan view illustrating a portion of constituents of the display device according to an embodiment of the inventive concept. FIG. 12 illustrates a planar arrangement relationship when one pad electrode PD1 included in the display panel and one first bump electrode BP1-1 correspondingly arranged thereto are bonded. FIG. 12 illustrates a case in which a predetermined misalignment occurs in one direction when one pad electrode PD1 and one first bump electrode BP1-1 disposed corresponding thereto are bonded. Each of the plurality of first protrusion members PP1 may be disposed on the bottom surface DC-DS (see FIG. 8) of the driver-integrated circuit DC-B (see FIG. 8), but for convenience of explanation, the plurality of first protrusion members PP1 are illustrated in dotted lines in FIG. 12.

Referring to FIG. 12, when the first bump electrode BP1-1 is bonded to the corresponding pad electrode PD1, the misalignment may occur in one direction. For example, the bonding may be performed with the misalignment by a predetermined width AM in the first direction DR1. In the first bump electrode BP1-1 according to an embodiment, as described above, the plurality of first row protrusion members PP-a and the plurality of second row protrusion members PP-b may be arranged in the zigzag shape in the diagonal directions DR-a and DR-b as the progressing direction, and the plurality of third row protrusion members PP-c and the plurality of fourth row protrusion members PP-d may be arranged in the zigzag shape in the diagonal directions DR-a and DR-b as the progressing direction. Therefore, even if the misalignment occurs, the contact area between the corresponding first bump electrode BP1-1 and the pad electrode PD1 may be secured, and thus, the electrical connection characteristics of the first bump electrode BP1-1 and the pad electrode PD1 may be improved.

In an embodiment, the display device may include the bump electrode DC-BP included in the driver including the protrusion member and the bonding layer, and the bonding layer may have a shape that is in direct contact with the corresponding pad electrode, and thus, even if the first adhesive layer that bonds the display panel to the driver does not include the separate conductive particles such as the conductive balls, the bump electrode of the driver and the pad electrode of the display panel may be electrically connected. Thus, even if the display panel and the driver are misaligned, short circuit due to the conductive particles such as the conductive balls may not occur, and thus, electrical connection characteristics between the pad electrode and the bump electrode may be improved.

The protrusion members included in each of the bump electrodes included in the driver may include the plurality of row protrusion members, and at least some of the row protrusion members may be arranged to not align with each other in the second direction, which is a spaced direction between the rows. Thus, the plurality of row protrusion members may be arranged in the zigzag shape in the diagonal direction as the progressing direction. In the display device according to an embodiment, the protrusion members included in each of the bump electrodes may include the plurality of row protrusion members arranged in the zigzag shape, and thus, even if the misalignment of the display panel and the driver occurs during the process of pressing the display panel and the driver, a minimum contact area between the pad electrode and the bump electrode may be secured. Therefore, the electrical connection characteristics between the bump electrodes and the pad electrodes may be uniformly controlled to improve the reliability of the display device including the driver.

In the embodiment of the display device, each of the bump electrodes included in the driver may include the plurality of row protrusion members, and the plurality of row protrusion members may be arranged in the zigzag shape with the diagonal direction as the progressing direction. Therefore, even if the display panel and the driver are misaligned during the process of compressing the display panel and the driver, the minimum contact area between the pad electrode and the bump electrode may be secured. Therefore, the electrical connection characteristics between the bump electrodes and the pad electrodes may be uniformly controlled to improve the reliability of the display device including the driver.

It will be apparent to those skilled in the art that various modifications and variations may be made in the inventive concept. Thus, it is intended that the present disclosure covers the modifications and variations of this invention provided they come within the scope of the appended claims and their equivalents.

Hence, the real protective scope of the inventive concept shall be determined by the technical scope of the accompanying claims.

What is claimed is:

1. A display device comprising:
a display panel comprising a display area on which a pixel is disposed and a non-display area on which a plurality of pad electrodes are disposed; and
a driver disposed on the display panel and comprising a plurality of bump electrodes, which are disposed to correspond to the plurality of pad electrodes, respectively,
wherein each of the plurality of bump electrodes comprises:
a plurality of protrusion members protruding to be adjacent to the display panel; and
a bonding layer which is configured to cover each of the plurality of protrusion members and which comprises a metal, a portion of the bonding layer is in contact with one of the plurality of pad electrodes,
wherein the plurality of protrusion members comprise:
a plurality of first row protrusion members arranged in a first direction; and
a plurality of second row protrusion members spaced apart from the plurality of first row protrusion members in a second direction crossing the first direction and arranged along the first direction, and
wherein at least some of the plurality of first row protrusion members and the plurality of second row protrusion members are disposed alternately to not align with each other in the second direction.

2. The display device of claim 1, further comprising a first adhesive layer disposed between the display panel and the driver to bond the display panel to the driver,
wherein the first adhesive layer comprises a non-conductive film.

3. The display device of claim 1, wherein the driver further comprises a driver-integrated circuit that includes a base surface adjacent to the display panel, and
wherein the plurality of bump electrodes are disposed between the base surface and the display panel.

4. The display device of claim 3, wherein each of the plurality of bump electrodes comprises an intermediate layer disposed between each of the plurality of protrusion members and the bonding layer.

5. The display device of claim 1, wherein the plurality of protrusion members further comprise:
a plurality of third row protrusion members spaced apart from the plurality of first row protrusion members and the plurality of second row protrusion members in the second direction and arranged along the first direction; and
a plurality of fourth row protrusion members spaced apart from the plurality of first row protrusion members, the plurality of second row protrusion members, and the plurality of third row protrusion members in the second direction and arranged along the first direction.

6. The display device of claim 5, wherein at least some of the plurality of second row protrusion members and the plurality of third row protrusion members are arranged parallel to the second direction, and
wherein at least some of the plurality of first row protrusion members and the plurality of fourth row protrusion members are arranged parallel to the second direction.

7. The display device of claim 5, wherein at least some of the plurality of first row protrusion members and the plurality of third row protrusion members are arranged parallel to the second direction, and
at least some of the plurality of second row protrusion members and the plurality of fourth row protrusion members are arranged parallel to the second direction.

8. The display device of claim 5, wherein the sum of the number of plurality of first row protrusion members and the number of plurality of second row protrusion members is greater than that of the number of plurality of third row protrusion members and the number of fourth row protrusion members.

9. The display device of claim 5, wherein each of the plurality of bump electrodes comprises:
a first connection area on which the plurality of first row protrusion members and the plurality of second row protrusion members are disposed;
a second connection area on which the plurality of third row protrusion members and the plurality of fourth row protrusion members are disposed; and
an inspection area on which the plurality of protrusion members are not disposed,
wherein the inspection area is disposed between the first connection area and the second connection area on a plane.

10. The display device of claim 5, wherein each of the plurality of bump electrodes comprises:
a first connection area on which the plurality of first row protrusion members and the plurality of second row protrusion members are disposed;
a second connection area on which the plurality of third row protrusion members and the plurality of fourth row protrusion members are disposed; and
an inspection area on which the plurality of protrusion members are not disposed,
wherein the inspection area is disposed at one side of one of the first connection area and the second connection area on a plane and is spaced apart from the other.

11. The display device of claim 1, wherein the number of plurality of first row protrusion members is less than the number of plurality of second row protrusion members.

12. The display device of claim 1, wherein, when a surface area of each of the plurality of bump electrodes is defined as A, and a product of a surface area and the number of each of the plurality of protruding members comprised in the plurality of bump electrodes is defined as B,
following Equation 1 is satisfied:
0.0012≤B/A≤0.0146 [Equation 1].

13. The display device of claim 1, wherein each of the plurality of protrusion members comprises a polymer material.

14. The display device of claim 1, wherein each of the plurality of protrusion members has a width that gradually decreases towards the display panel.

15. The display device of claim 1, wherein the plurality of bump electrodes comprise:
a plurality of first bump electrodes arranged along the first direction; and
a plurality of second bump electrodes spaced apart from the plurality of first bump electrodes in the second direction and arranged along the first direction,
wherein the driver comprises:
a first long side extending in the first direction;
a second long side extending in the first direction and spaced apart from the first long side along the second direction;
a first short side extending in the second direction to connect the first long side to the second long side; and
a second short side extending in the second direction and spaced apart from the first short side along the first direction,
wherein the plurality of first bump electrodes are disposed adjacent to the first long side, and
the plurality of second bump electrodes are disposed adjacent to the second long side.

16. The display device of claim 1, wherein each of the plurality of first row protrusion members is spaced apart from each of the plurality of second row protrusion members in a diagonal direction that is a direction between the first direction and the second direction.

17. A display device comprising:
a display panel comprising a display area on which a pixel is disposed and a non-display area on which a plurality of pad electrodes are disposed; and
a driver disposed on the display panel and comprising a plurality of bump electrodes, which are disposed to correspond to the plurality of pad electrodes, respectively,
wherein the plurality of bump electrodes comprise:
a plurality of protrusion members protruding to be adjacent to the display panel; and
a bonding layer which is configured to cover each of the plurality of protrusion members, a portion of the bonding layer is in contact with one of the plurality of pad electrodes,
wherein the plurality of protrusion members comprise:
a plurality of first row protrusion members arranged in a first direction; and
a plurality of second row protrusion members spaced apart from the plurality of first row protrusion members in a second direction crossing the first direction and arranged along the first direction, and
wherein each of the plurality of first row protrusion members is spaced apart from each of the plurality of second row protrusion members in a diagonal direction that is a direction between the first direction and the second direction.

18. The display device of claim 17, wherein the plurality of protrusion members further comprise:
a plurality of third row protrusion members spaced apart from the plurality of first row protrusion members and the plurality of second row protrusion members in the second direction and arranged along the first direction; and
a plurality of fourth row protrusion members spaced apart from the plurality of first row protrusion members, the plurality of second row protrusion members, and the plurality of third row protrusion members in the second direction and arranged along the first direction,
wherein each of the plurality of third row protrusion members is spaced apart from each of the plurality of fourth row protrusion members in the diagonal direction.

19. The display device of claim 18, wherein at least some of each of the plurality of second row protrusion members and each of the plurality of third row protrusion members are arranged parallel to the second direction, and
at least some of each of the plurality of first row protrusion members and each of the plurality of fourth row protrusion members are arranged parallel to the second direction.

20. An electronic device comprising:
a display panel comprising a display area on which a pixel is disposed and a non-display area on which a plurality of pad electrodes are disposed;
electronic modules electrically connected to the display panel;
a driver disposed on the display panel and comprising a plurality of bump electrodes, which are disposed to correspond to the plurality of pad electrodes, respectively; and
a first adhesive layer disposed between the display panel and the driver to bond the display panel to the driver,
wherein the first adhesive layer comprises a non-conductive film,
wherein each of the plurality of the plurality of bump electrodes comprises:
a plurality of protrusion members protruding to be adjacent to the display panel; and
a bonding layer which is configured to cover each of the plurality of protrusion members, a portion of the bonding layer is in contact with one of the plurality of pad electrodes,
wherein the plurality of protrusion members comprise:
a plurality of first row protrusion members arranged in a first direction; and
a plurality of second row protrusion members spaced apart from the plurality of first row protrusion members in a second direction crossing the first direction and arranged along the first direction, and
wherein at least some of the plurality of first row protrusion members and the plurality of second row protrusion members are disposed alternately to not-align with each other in the second direction.
